(19) United States
(12) Patent Application Publication
(10) Pub. No.: US 2019/0096837 A1
(43) Pub. Date: Mar. 28, 2019

(54) METHOD FOR PREPARING A SEMICONDUCTOR STRUCTURE

(71) Applicant: NANYA TECHNOLOGY CORPORATION, NEW TAIPEI CITY (TW)

(72) Inventor: Po Chun LIN, CHANGHUA CITY (TW)

(21) Appl. No.: 16/198,127

(22) Filed: Nov. 21, 2018

Related U.S. Application Data
(62) Division of application No. 15/851,515, filed on Dec. 21, 2017.
Application No. 15/851,515 is a division of application No. 15/271,603, filed on Sep. 21, 2016, now abandoned.

(51) Int. Cl. H01L 23/00; H01L 29/06; H01L 23/58

(52) U.S. Cl. CPC H01L 24/13; H01L 23/585; H01L 29/06; H01L 24/85; H01L 24/81; H01L 24/05; H01L 2224/04042; H01L 2224/11312; H01L 2224/8121; H01L 2224/73265; H01L 2224/48227; H01L 2224/32225; H01L 2224/48091; H01L 2924/3512; H01L 2224/0401; H01L 2224/11462; H01L 2224/13025; H01L 2224/13021; H01L 24/11

(57) ABSTRACT

A method for preparing a semiconductor structure includes the steps of providing a substrate; forming a recess over the substrate; disposing a conductive layer over the substrate; and disposing a passivation over the substrate to at least partially cover the conductive layer.

### PRIORITY CLAIM AND CROSS-REFERENCE

This application is a divisional application of U.S. patent application Ser. No. 15/851,515, filed Dec. 21, 2017, which is a divisional application of U.S. patent application Ser. No. 15/271,603, filed Sep. 21, 2016. The entireties of the above-mentioned patent applications are hereby incorporated by reference herein and made a part of this specification.

### TECHNICAL FIELD

The present disclosure relates to a method for preparing a semiconductor structure comprising a conductive layer disposed over a substrate and within a recess recessing into the substrate.

### DISCUSSION OF THE BACKGROUND

Semiconductor devices are essential for many modern applications. With the advancement of electronic technology, semiconductor devices are becoming increasingly smaller in size while having greater functionality and greater amounts of integrated circuitry. Due to the miniaturized scale of semiconductor devices, wafer level chip scale packaging (WLCSP) is widely used for manufacturing. Numerous manufacturing steps are implemented within such small semiconductor devices.

However, the manufacturing of semiconductor devices in a miniaturized scale is becoming more complicated. An increase in the complexity of manufacturing semiconductor devices may cause deficiencies, such as poor electrical interconnection, development of cracks or delamination of components. As such, there are many challenges for modifying the structure and manufacturing of semiconductor devices.

This “Discussion of the Background” section is provided for background information only. The statements in this “Discussion of the Background” are not an admission that the subject matter disclosed in this “Discussion of the Background” section constitutes prior art to the present disclosure, and no part of this “Discussion of the Background” section may be used as an admission that any part of this application, including this “Discussion of the Background” section, constitutes prior art to the present disclosure.

### SUMMARY

One aspect of the present disclosure provides a semiconductor structure comprising a substrate which includes a first surface, a second surface opposite to the first surface and a recess recessed from the first surface towards the second surface; a conductive layer disposed over the first surface and within the recess; and a passivation disposed over the first surface and partially covering the conductive layer, wherein the conductive layer disposed within the recess is exposed from the passivation.

In some embodiments, the conductive layer is disposed conformal to a sidewall of the recess.

In some embodiments, the conductive layer exposed from the passivation is configured to receive an interconnect structure, and the interconnect structure is a conductive bump, a conductive wire or a conductive stud.

In some embodiments, at least a portion of the interconnect structure is surrounded by the conductive layer and the substrate.

In some embodiments, the semiconductor structure further includes a conductive structure disposed within the substrate and electrically connected to the conductive layer.

In some embodiments, the conductive structure is a metallic member or a transistor.

In some embodiments, the semiconductor structure further includes an under bump metallization (UBM) layer disposed within the recess, wherein the UBM layer is configured to receive an interconnect structure.

In some embodiments, the substrate includes silicon, silicon oxide, glass, ceramic or organic material.

Another aspect of the present disclosure provides a semiconductor structure comprising a substrate including a first surface, a second surface opposite to the first surface and a recess recessed from the first surface towards the second surface; a conductive layer disposed over the first surface; a passivation disposed over the first surface and at least partially covering the conductive layer; an interconnect structure disposed within the recess and electrically connected to the conductive layer.

In some embodiments, at least a portion of the interconnect structure is surrounded by the substrate.

In some embodiments, the semiconductor structure further includes an under bump metallization (UBM) layer disposed within the recess exposed from the passivation.

In some embodiments, the UBM layer is surrounded by the conductive layer and the substrate.

In some embodiments, the interconnect structure is electrically connected to a conductive structure disposed within the substrate through the conductive layer.

Another aspect of the present disclosure provides a method of manufacturing a semiconductor structure which includes providing a substrate; forming a recess over the substrate; disposing a conductive layer over the substrate; disposing a passivation over the substrate to at least partially cover the conductive layer.

In some embodiments, the conductive layer is disposed within the recess or conformal to a sidewall of the recess.

In some embodiments, the conductive layer is disposed by electroplating or sputtering.

In some embodiments, the recess is formed by disposing a patterned mask over the substrate and removing a portion of the substrate.

In some embodiments, the recess is formed by disposing a patterned mask over the passivation and removing a portion of the passivation, a portion of the conductive layer and a portion of the substrate.

In some embodiments, the recess is formed by photolithography and etching.

In some embodiments, the method further includes disposing an under bump metallization (UBM) layer within the recess exposed from the passivation; or disposing an interconnect structure over the conductive layer to electrically connect the interconnect structure with the conductive layer; or reflowing the interconnect structure; or attaching the semiconductor structure over a second substrate; or wire bonding the conductive layer with a second substrate.

The foregoing has outlined rather broadly the features and technical advantages of the present disclosure in order that the detailed description of the disclosure that follows may be better understood. Additional features and advantages of the disclosure will be described hereinafter, and they form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

A more complete understanding of the present disclosure may be derived by referring to the detailed description and claims when considered in connection with the Figures, where like reference numbers refer to similar elements throughout the Figures.

FIG. 1 is a schematic cross-sectional view of a semiconductor structure in accordance with some embodiments of the present disclosure.

FIG. 2 is a schematic cross-sectional view of a semiconductor structure in accordance with some embodiments of the present disclosure.

FIG. 3 is a schematic cross-sectional view of a semiconductor structure having an interconnect structure in accordance with some embodiments of the present disclosure.

FIG. 4 is a schematic cross-sectional view of a semiconductor structure having an interconnect structure in accordance with some embodiments of the present disclosure.

FIG. 5 is a schematic cross-sectional view of a semiconductor structure having an UBM layer in accordance with some embodiments of the present disclosure.

FIG. 6 is a schematic cross-sectional view of a semiconductor structure having an UBM layer in accordance with some embodiments of the present disclosure.

FIG. 7 is a schematic cross-sectional view of a semiconductor structure having a wire bonding structure in accordance with some embodiments of the present disclosure.

FIG. 8 is a schematic cross-sectional view of a semiconductor structure having a wire bonding structure in accordance with some embodiments of the present disclosure.

FIG. 9 is a schematic cross-sectional view of a package including a semiconductor structure integrated with a substrate in accordance with some embodiments of the present disclosure.

FIG. 10 is a schematic cross-sectional view of a semiconductor structure having a conductive layer disposed over a substrate in accordance with some embodiments of the present disclosure.

FIG. 11 is a schematic cross-sectional view of a semiconductor structure having a portion of a conductive layer exposed from passivation in accordance with some embodiments of the present disclosure.

FIG. 12 is a schematic cross-sectional view of a semiconductor structure having a conductive layer disposed over a substrate in accordance with some embodiments of the present disclosure.

FIG. 13 is a flow chart of a method of manufacturing a semiconductor structure in accordance with some embodiments of the present disclosure.

FIGS. 14-25 are schematic views of manufacturing the semiconductor structure by the method of FIG. 13 in accordance with some embodiments of the present disclosure.

FIG. 26 is a flow chart of a method of manufacturing a semiconductor structure in accordance with some embodiments of the present disclosure.

FIGS. 27-31 are schematic views of manufacturing the semiconductor structure by the method of FIG. 26 in accordance with some embodiments of the present disclosure.

FIG. 32 is a flow chart of a method of manufacturing a semiconductor structure in accordance with some embodiments of the present disclosure.

FIGS. 33-46 are schematic views of manufacturing the semiconductor structure by the method of FIG. 32 in accordance with some embodiments of the present disclosure.

### DETAILED DESCRIPTION

The following description of the disclosure accompanies drawings, which are incorporated in and constitute a part of this specification, and illustrate embodiments of the disclosure, but the disclosure is not limited to the embodiments. In addition, the following embodiments can be properly integrated to complete another embodiment.

References to “one embodiment,” “an embodiment,” “exemplary embodiment,” “other embodiments,” “another embodiment,” etc. indicate that the embodiment(s) of the disclosure so described may include a particular feature, structure, or characteristic, but not every embodiment necessarily includes the particular feature, structure, or characteristic. Further, repeated use of the phrase “in the embodiment” does not necessarily refer to the same embodiment, although it may.

The present disclosure is directed to a semiconductor structure comprising a conductive layer disposed over a substrate and within a recess recessing into a substrate. In order to make the present disclosure completely comprehensible, detailed steps and structures are provided in the following description. Obviously, implementation of the present disclosure does not limit special details known by persons skilled in the art. In addition, known structures and steps are not described in detail, so as not to unnecessarily limit the present disclosure. Preferred embodiments of the present disclosure will be described below in detail. However, in addition to the detailed description, the present disclosure may also be widely implemented in other embodiments. The scope of the present disclosure is not limited to the detailed description, and is defined by the claims.

A semiconductor structure is electrically connected with another chip or package through an interconnect structure, such as a bump, a pillar, a wire or the like. The interconnect structure is disposed over the semiconductor structure. Upon disposing of the interconnect structure, a stress or a force would be acted over the semiconductor structure and cause damage to the interconnect structure, as well as components under the interconnect structure. As such, a crack may be developed in the interconnect structure or may even propagate into the components of the semiconductor structure. Delamination of components may occur. As a result, failure of the electrical connection would occur.

In the present disclosure, a semiconductor structure is disclosed. The semiconductor structure comprises a substrate having a recess, and a conductive layer disposed over the substrate and the recess. The recess is indented into the substrate, and the conductive layer is disposed within or conformal to the recess. The conductive layer is recessed into the substrate. An interconnect structure such as a conductive bump, a wire or a stud is disposed over the conductive layer and within the recess. The interconnect structure is at least partially disposed within the substrate, which can reduce an overall thickness or height of the semiconductor structure.

Furthermore, the recessed conductive layer can receive the interconnect structure in greater size. The interconnect structure can provide elasticity and can relieve a stress over the semiconductor structure during manufacturing or developed during thermal processes. Therefore, cracks in the semiconductor structure and delamination of components can be minimized or prevented. The reliability of the semiconductor structure can be improved.

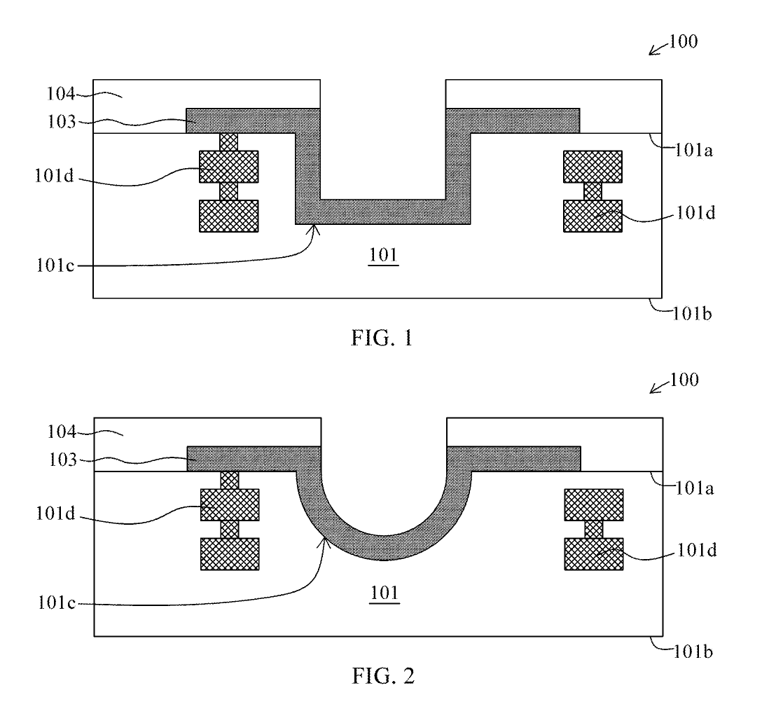

FIG. 1 is a cross-sectional view of a semiconductor structure 100 in accordance with some embodiments of the present disclosure. In some embodiments, the semiconductor structure 100 includes a substrate 101, a conductive layer 103 and a passivation 104. In some embodiments, the semiconductor structure 100 is a part of a die, a chip or a semiconductor package.

In some embodiments, the substrate 101 is a semiconductive substrate. In some embodiments, the substrate 101 is a wafer. In some embodiments, the substrate 101 includes semiconductive material such as silicon, germanium, gallium, arsenic, and combinations thereof. In some embodiments, the substrate 101 is a silicon substrate. In some embodiments, the substrate 101 includes material such as ceramic, glass or the like. In some embodiments, the substrate 101 includes organic material. In some embodiments, the substrate 101 is a glass substrate. In some embodiments, the substrate 101 is a packaging substrate. In some embodiments, the substrate 101 is in a quadrilateral, rectangular, square, polygonal or any other suitable shapes.

In some embodiments, the substrate 101 includes a first surface 101a and a second surface 101b opposite to the first surface 101b. In some embodiments, the first surface 101a is a front side or an active side where the circuits or electrical components are disposed thereon. In some embodiments, the second surface 101b is a back side or an inactive side.

In some embodiments, the substrate 101 includes a recess 101c indented into the substrate 101. In some embodiments, the recess 101c is recessed from the first surface 101a towards the second surface 101b. In some embodiments, the recess 101c is recessed from the second surface 101b towards the first surface 101a. In some embodiments, the recess 101c is extended in a direction orthogonal to the first surface 101a or the second surface 101b.

In some embodiments, the substrate 101 is fabricated with a predetermined functional circuit thereon. In some embodiments, the substrate 101 includes several conductive traces and several electrical components disposed within the substrate 101. In some embodiments, a conductive structure 101d is disposed within the substrate. In some embodiments, the conductive structure 101d is a metallic member. In some embodiments, the conductive structure 101d includes several layers stacking over each other and electrically connected by vias. In some embodiments, the conductive structure 101d is extended between the first surface 101a and the second surface 101b. In some embodiments, the conductive structure 101d includes gold, silver, copper, nickel, tungsten, aluminum, palladium and/or alloys thereof. In some embodiments, the conductive structure 101d is a transistor or a diode. In some embodiments, the conductive structure 101d is electrically connected by conductive traces.

In some embodiments, the conductive layer 103 is disposed over the first surface 101a and within the recess 101c. In some embodiments, the conductive layer 103 is disposed along the first surface 101a and the recess 101c. In some embodiments, the conductive layer is disposed conformal to a sidewall of the recess 101c. In some embodiments, the conductive layer 103 is electrically connected to the conductive structure 101d. In some embodiments, the conductive layer 103 is coupled with at least a portion of the conductive structure 101d. In some embodiments, the conductive layer 103 includes gold, silver, copper, nickel, tungsten, aluminum, palladium and/or alloys thereof.

In some embodiments, the passivation 104 is disposed over the first surface 101a and partially covers the conductive layer 103. In some embodiments, the passivation 104 is configured to provide an electrical insulation and a moisture protection for the conductive layer 103 and the substrate 101. In some embodiments, the passivation 104 includes one or more layers of dielectric material stacking over each other. In some embodiments, the passivation 104 is formed with dielectric materials, such as elastomer, epoxy, polyimide, polymer, resin, oxide or the like.

In some embodiments, at least a portion of the conductive layer 103 is exposed from the passivation 104. In some embodiments, the conductive layer 103 disposed within the recess 101c is exposed from the passivation 104. In some embodiments, the conductive layer 103 exposed from the passivation 104 is configured to receive an interconnect structure such as a conductive bump, a conductive wire, a conductive stud, a bonding wire, etc.

FIG. 2 is a cross-sectional view of a semiconductor structure 100 which has similar configuration as described above or illustrated in FIG. 1. In some embodiments as shown in FIG. 2, the sidewall of the recess 101c is a hemispherical shape, and the conductive layer 103 is disposed conformal to the sidewall of the recess 101c in hemispherical shape.

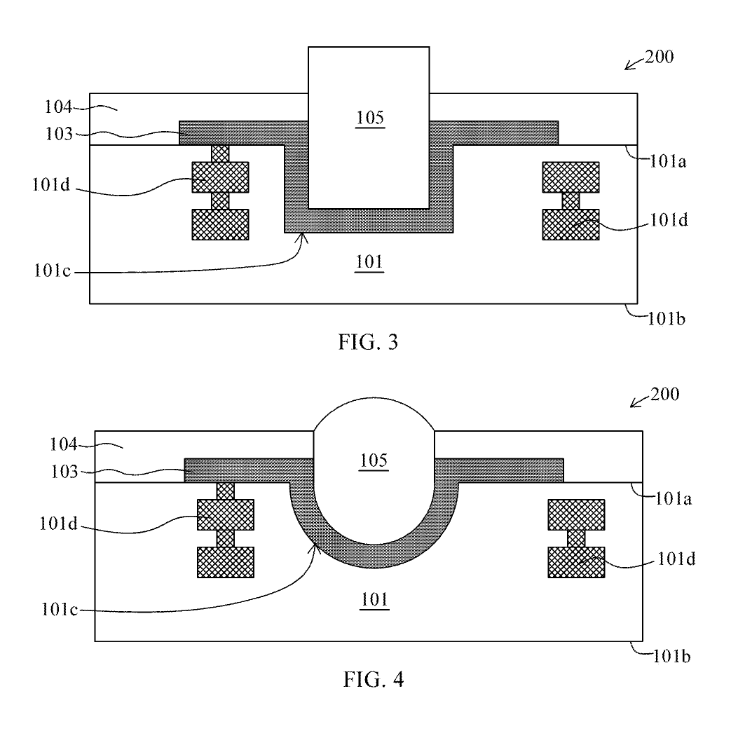

FIGS. 3 and 4 are cross-sectional views of a semiconductor structure 200 in accordance with some embodiments of the present disclosure. In some embodiments, the semiconductor structure 200 has similar configuration as the semiconductor structure 100 described above or illustrated in FIG. 1 or 2.

In some embodiments, the semiconductor structure 200 includes an interconnect structure 105 disposed over the conductive layer 103 exposed from the passivation 104. In some embodiments, the interconnect structure 105 is disposed within the recess 101c. In some embodiments, the interconnect structure 105 is electrically connected to or coupled with the conductive layer 103. In some embodiments, the interconnect structure 105 is electrically connected to the conductive structure 101d through the conductive layer 103. In some embodiments, the interconnect structure 105 is at least partially surrounded by the substrate 101, the conductive layer 103 and the passivation 104. In some embodiments, the interconnect structure 105 is at least partially protruded from the passivation 104.

In some embodiments, the interconnect structure 105 is configured to bond with another conductive member, a chip or a package. In some embodiments, the interconnect structure 105 is a conductive bump, a conductive pillar, a conductive wire, a conductive stud or a bonding wire or the like. In some embodiments, the interconnect structure 105 includes conductive material such as lead, tin, copper, gold, silver, nickel or combination thereof. In some embodiments, the interconnect structure 105 is a solder joint, a solder bump, a solder ball, a ball grid array (BGA) ball, a controlled collapse chip connection (C4) bump, a microbump or the like. In some embodiments, the interconnect structure 105 is in a cylindrical shape, a spherical or hemispherical shape.

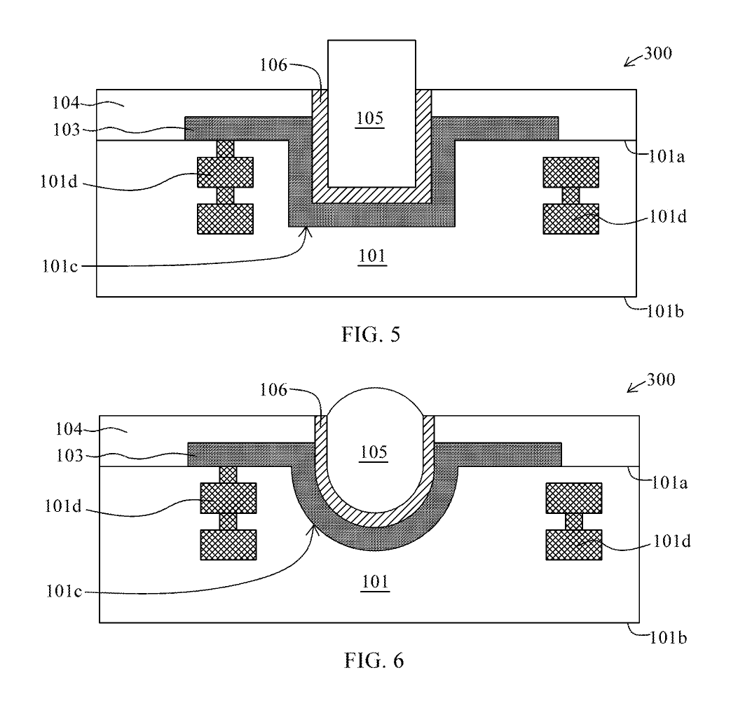

FIGS. 5 and 6 are cross-sectional views of a semiconductor structure 300 in accordance with some embodiments of the present disclosure. In some embodiments, the semiconductor structure 300 has similar configuration as the semiconductor structure 100 described above or illustrated in FIG. 1 or 2 or as the semiconductor structure 200 described above or illustrated in FIG. 3 or 4.

In some embodiments, the semiconductor structure 300 includes an under bump metallization (UBM) layer 106 over the conductive layer 103. In some embodiments, the UBM layer 106 is disposed within the recess 101c. In some embodiments, the UBM layer 106 is disposed conformal to the conductive layer 103. In some embodiments, the UBM layer 106 is surrounded by the substrate 101, the conductive layer 103 and the passivation 104. In some embodiments, the UBM layer 106 is disposed over the conductive layer 103 exposed from the passivation 104.

In some embodiments, the UBM layer 106 is configured to receive an interconnect structure. In some embodiments, the UBM layer 106 is disposed between the interconnect structure 105 and the conductive layer 103. In some embodiments, the interconnect structure 105 is electrically connected to the conductive structure 101d through the UBM layer 106 and the conductive layer 103. In some embodiments, the UBM layer 106 surrounds the interconnect structure 105.

In some embodiments, the UBM layer 106 includes chromium, copper, gold, titanium, tungsten, nickel or etc. In some embodiments, the UBM layer 106 includes an adhesion layer, a barrier layer or a wettable layer. In some embodiments, the adhesion layer includes titanium, tungsten or etc. In some embodiments, the barrier layer includes nickel or etc. In some embodiments, the wettable layer includes copper, gold or etc.

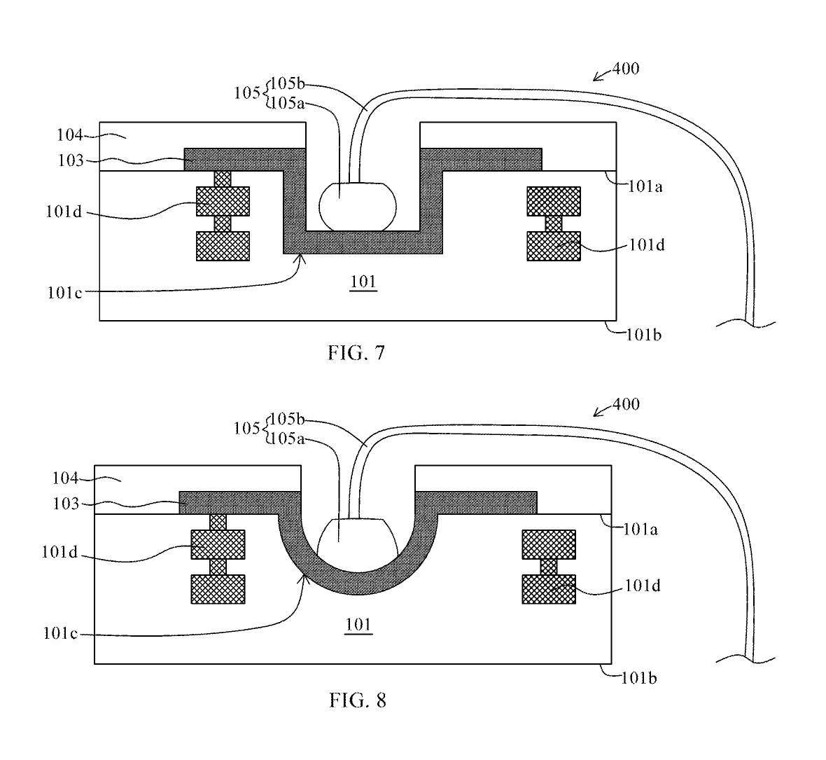

FIGS. 7 and 8 are cross-sectional views of a semiconductor structure 400 in accordance with some embodiments of the present disclosure. In some embodiments, the semiconductor structure 400 has similar configuration as the semiconductor structure 100 described above or illustrated in FIG. 1 or 2.

In some embodiments, the semiconductor structure 400 includes an interconnect structure 105 which is a wire bonding structure. In some embodiments, the interconnect structure 105 includes a stud 105a disposed over the conductive layer 103, and a wire 105b extended from the stud 105a and configured to bond or electrically connect with a conductive member or another interconnect structure.

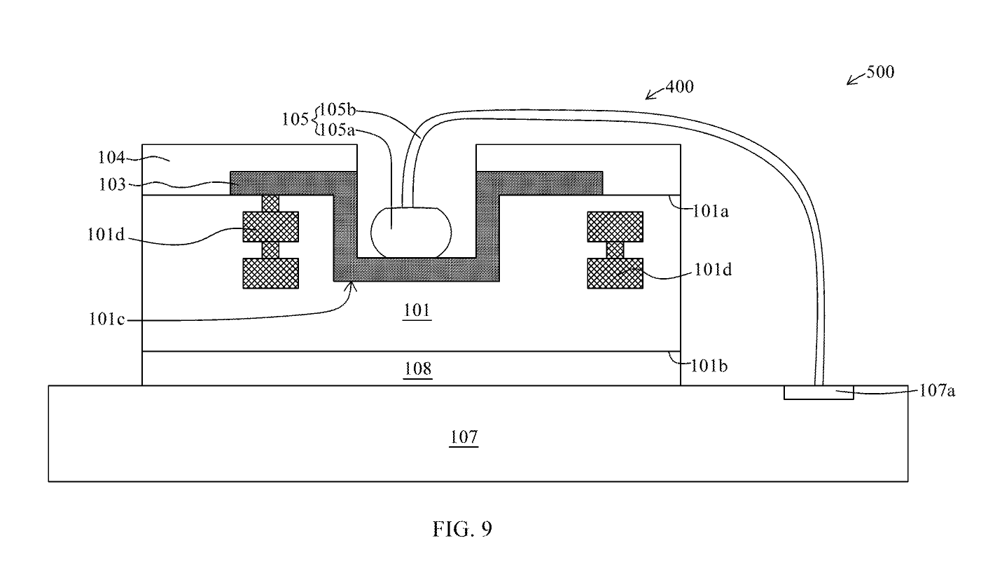

FIG. 9 is a cross-sectional view of a package 500 in accordance with some embodiments of the present disclosure. In some embodiments, the package 500 includes the semiconductor structure 400 which has similar configuration as described above or illustrated in FIG. 7 or 8.

In some embodiments, the package 500 includes a second substrate 107. In some embodiments, the second substrate 107 is a substrate or a wafer. In some embodiments, the second substrate 107 is a printed circuit board (PCB). In some embodiments, the second substrate 107 includes a bond pad 107a disposed over the second substrate 107 and configured to receive a conductive member or an interconnect structure.

In some embodiments, the semiconductor structure 400 is disposed over the second substrate 107. In some embodiments, the semiconductor structure 400 is attached to the second substrate 107 by an adhesive such as a die attach film (DAF). In some embodiments, the stud 105b is bonded with the bond pad 107a, such that the substrate 101 is electrically connected to the second substrate 107 through the conductive layer 103, the stud 105a, the wire 105b and the bond pad 107a.

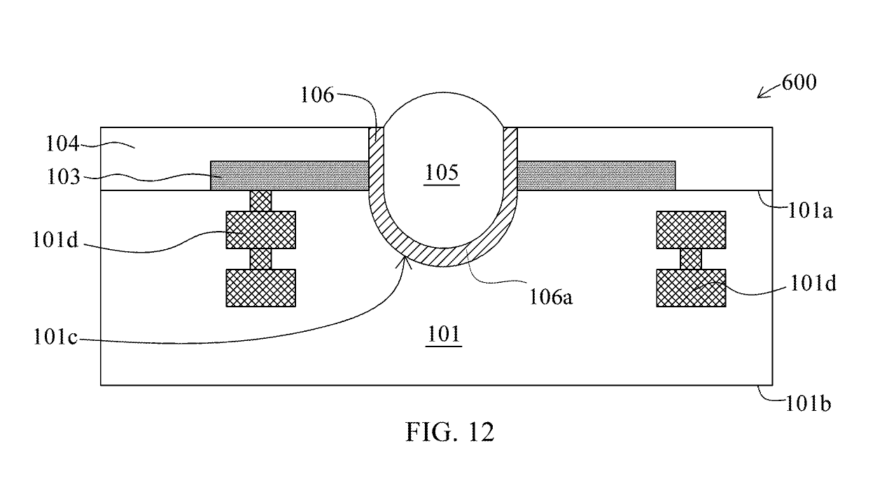

FIGS. 10-12 are cross-sectional views of a semiconductor structure 600 in accordance with some embodiments of the present disclosure. In some embodiments, the semiconductor structure 600 has similar configuration as the semiconductor structure 300 described above or illustrated in FIG. 5 or 6.

In some embodiments, the conductive layer 103 is not disposed within the recess 101c. In some embodiments, the conductive layer 103 is only disposed over the first surface 101a. In some embodiments, a portion of the conductive layer 103 is exposed from the passivation 104. In some embodiments, a side portion of the conductive layer 103 is exposed from the passivation 104.

In some embodiments, the UBM layer 106 is disposed within the recess 101c and disposed over the conductive layer 103 exposed from the passivation 104. The UBM layer 106 includes a bottom position 106a within the recess 101c. The bottom portion 106a of the UBM layer 106 is lower than the conductive layer 103. In some embodiments, the UBM layer 106 is disposed conformal to the recess 101c and coupled with at least a portion of the conductive layer 103, such that the UBM layer 106 is electrically connected to the conductive layer 103. In some embodiments, the UBM layer 106 is electrically connected to the conductive structure 101d through the conductive layer 103. In some embodiments, the UBM layer 106 is surrounded by the conductive layer 103 and the substrate 101.

In some embodiments, the interconnect structure 105 is disposed within the recess 101c and surrounded by the UBM layer 106. In some embodiments, the interconnect structure 105 is electrically connected to the conductive structure 101d through the conductive layer 103 and the UBM layer 106.

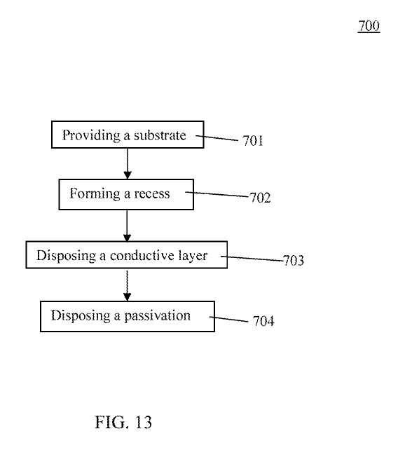

In the present disclosure, a method of manufacturing a semiconductor structure is also disclosed. In some embodiments, the semiconductor structure can be formed by a method 700 of FIG. 13. The method 700 includes a number of operations and the description and illustration are not deemed as a limitation as the sequence of the operations. The method 700 includes a number of steps (701, 702, 703 and 704).

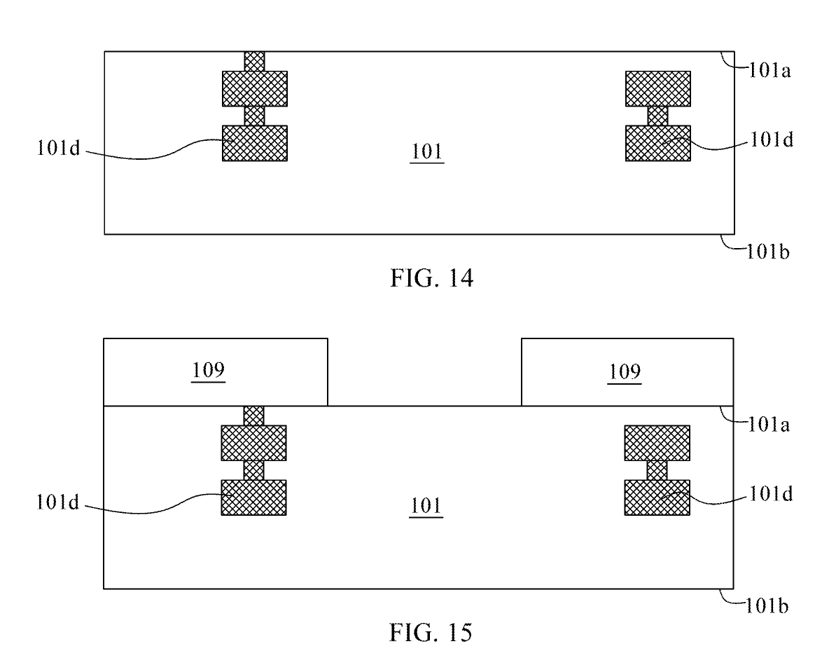

In step 701, a substrate 101 is provided or received as shown in FIG. 14. In some embodiments, the substrate 101 is a semiconductive substrate. In some embodiments, the substrate 101 is a wafer. In some embodiments, the substrate 101 includes semiconductive material such as silicon, germanium, gallium, arsenic, and combinations thereof. In some embodiments, the substrate 101 is a silicon substrate.

In some embodiments, the substrate 101 includes a first surface 101a and a second surface 101b opposite to the first surface 101b. In some embodiments, the first surface 101a is a front side or an active side where the circuits or electrical components are disposed thereon. In some embodiments, the second surface 101b is a back side or an inactive side.

In some embodiments, the substrate 101 is fabricated with a predetermined functional circuit thereon. In some embodiments, the substrate 101 includes several conductive traces and several electrical components disposed within the substrate 101. In some embodiments, a conductive structure 101d is formed within the substrate. In some embodiments, the conductive structure 101d is formed by removing some portions of the substrate 101 and disposing conductive material. is In some embodiments, the portions of the substrate 101 are removed by photolithography, etching or any other suitable processes. In some embodiments, the conductive material is disposed by sputtering, electroplating or any other suitable processes. In some embodiments, the conductive structure 101d is a metallic member. In some embodiments, the conductive structure 101d includes several layers stacking over each other and electrically connected by vias. In some embodiments, the conductive structure 101d is extended between the first surface 101a and the second surface 101b. In some embodiments, the conductive structure 101d includes gold, silver, copper, nickel, tungsten, aluminum, palladium and/or alloys thereof. In some embodiments, the conductive structure 101d is a transistor or a diode. In some embodiments, the conductive structure 101d is electrically connected by conductive traces. In some embodiments, the conductive structure 101d has similar configuration as described above or illustrated in any one of FIGS. 1-12.

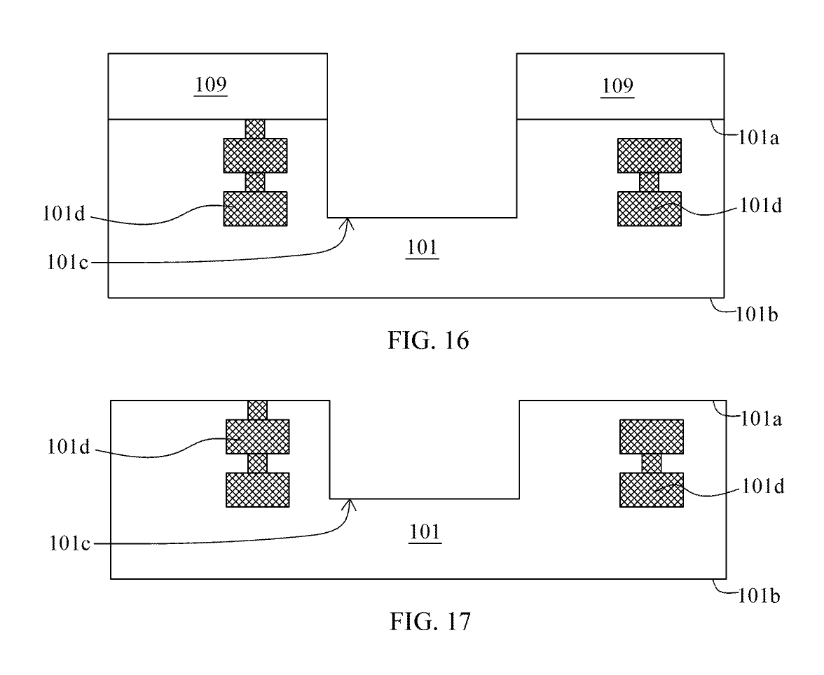

In step 702, a recess 101c is formed as shown in FIGS. 15-17. In some embodiments, the recess 101c is formed by removing a portion of the substrate 101. In some embodiments, the recess 101c is formed by photolithography, etching and any other suitable processes. In some embodiments, the recess 101c is formed by disposing a first patterned mask 109 over the substrate 101 as shown in FIG. 15, removing the portion of the substrate 101 exposed from the first patterned mask 109 as shown in FIG. 16, and then removing the first patterned mask 109 as shown in FIG. 17. In some embodiments, the first patterned mask 109 is formed by disposing a photoresist (PR) over the substrate 101, and then removing a portion of the PR corresponding to the portion of the substrate 101 to be removed. In some embodiments, the first patterned mask 109 is disposed over the first surface 101a. In some embodiments, the first patterned mask 109 is removed by etching, stripping or any other suitable processes after the formation of the recess 101c.

In some embodiments, the recess 101c is recessed from the first surface 101a towards the second surface 101b. In some embodiments, the recess 101c is extended in a direction orthogonal to the first surface 101a or the second surface 101b. In some embodiments, the recess 101c has similar configuration as described above or illustrated in any one of FIGS. 1-12.

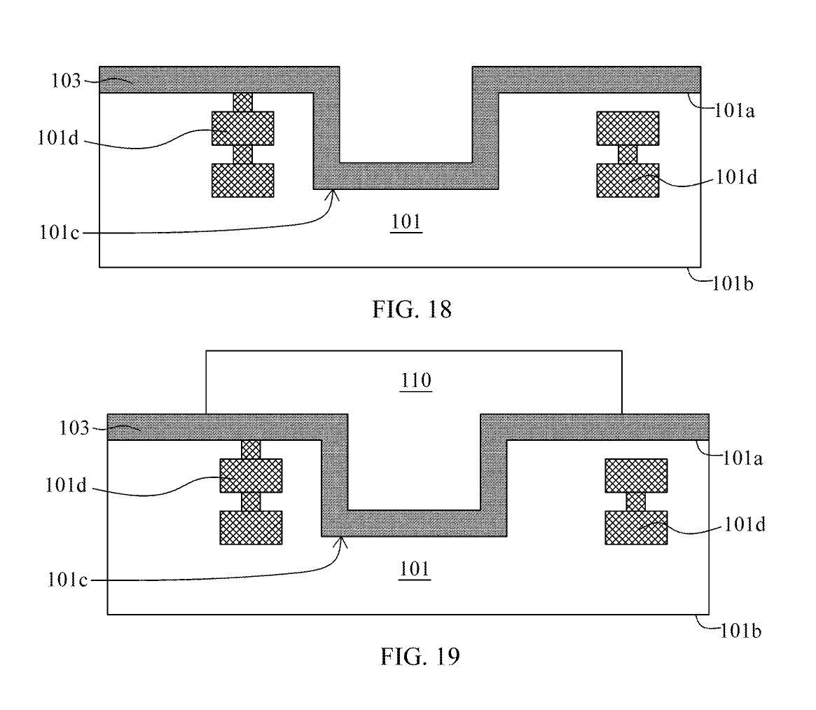

In step 703, a conductive layer 103 is disposed over the substrate 101 as shown in FIG. 18. In some embodiments, the conductive layer 103 is disposed over the first surface 101a and within the recess 101c. In some embodiments, the conductive layer 103 is disposed conformal to a sidewall of the recess 101c. In some embodiments, the conductive layer 103 is disposed by electroplating, sputtering or any other suitable operations. In some embodiments, the conductive layer 103 includes gold, silver, copper, nickel, tungsten, aluminum, palladium and/or alloys thereof. In some embodiments, the conductive layer 103 is electrically connected to the conductive structure 101d. In some embodiments, the conductive layer 103 is coupled with at least a portion of the conductive structure 101d.

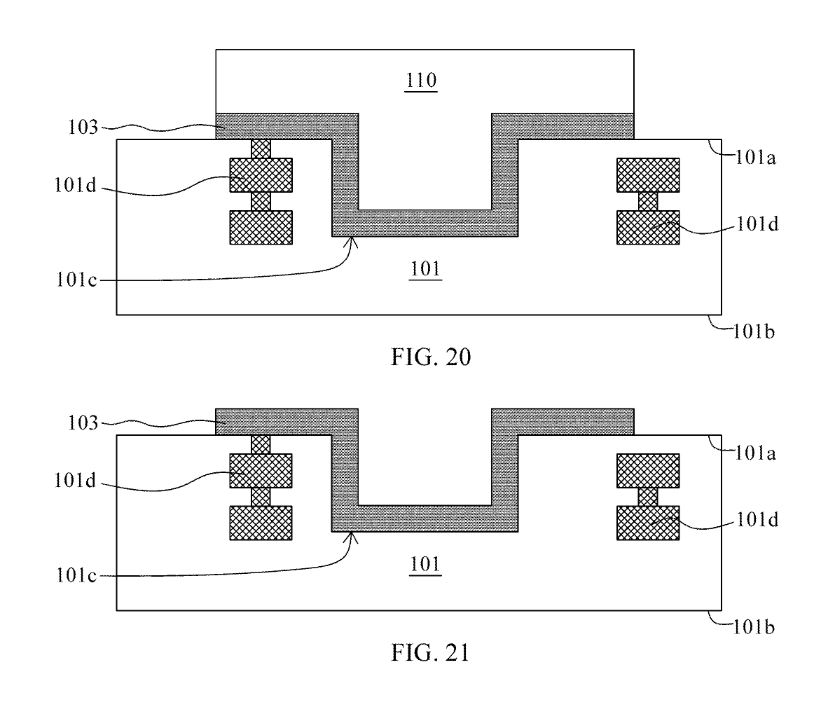

In some embodiments, some portions of the conductive layer 103 disposed over the first surface 101a are removed as shown in FIGS. 19-21. In some embodiments, a second patterned mask 110 is disposed over the conductive layer 103 as shown in FIG. 19, and some portions of the conductive layer 103 exposed from the second patterned mask 110 are removed as shown in FIG. 20, and then the second patterned mask 110 is removed as shown in FIG. 21. In some embodiments, the second patterned mask 110 is formed by disposing a photoresist (PR) over the conductive layer 103, and then removing a portion of the PR corresponding to the portions of the conductive layer 103 to be removed. In some embodiments, the second patterned mask 110 is removed by etching, stripping or any other suitable processes after the formation of the conductive layer 103. In some embodiments, the conductive layer 103 has similar configuration as described above or illustrated in any one of FIGS. 1-9.

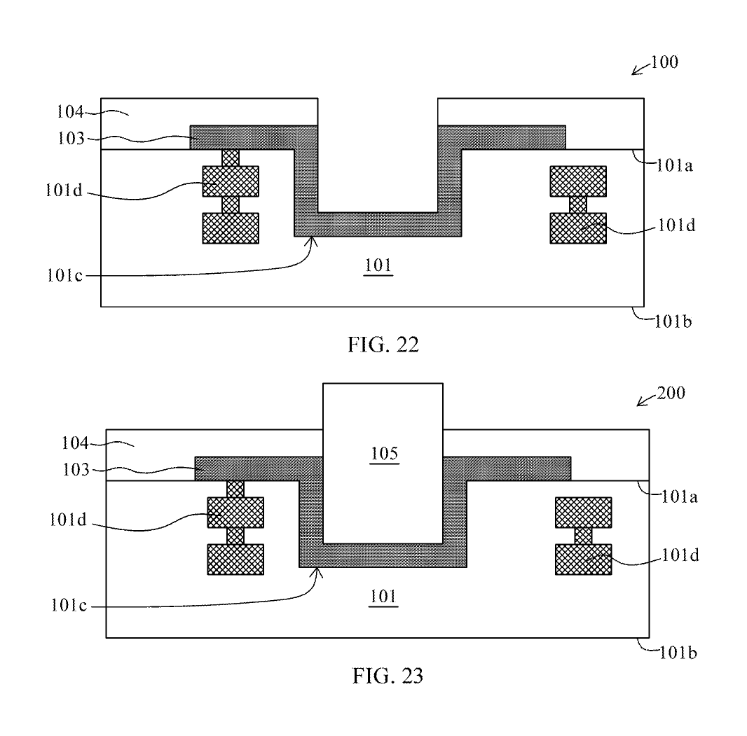

In step 704, a passivation 104 is disposed over the substrate 101 and the conductive layer 103 as shown in FIG. 22. In some embodiments, the passivation 104 at least partially covering the conductive layer 103, such that the conductive layer 103 disposed within the recess 101c is exposed from the passivation 104. In some embodiments, the passivation 104 is disposed by chemical vapor deposition (CVD), plasma-enhanced chemical vapor deposition (PECVD), spin coating or any other suitable processes. In some embodiments, the passivation 104 includes one or more layers of dielectric material stacking over each other. In some embodiments, the passivation 104 is formed with dielectric materials, such as elastomer, epoxy, polyimide, polymer, resin, oxide or the like.

In some embodiments, the passivation 104 has similar configuration as described above or illustrated in any one of FIGS. 1-12. In some embodiments, a semiconductor structure 100 is formed. In some embodiments, the semiconductor structure 100 has similar configuration as described above or illustrated in FIG. 1 or 2.

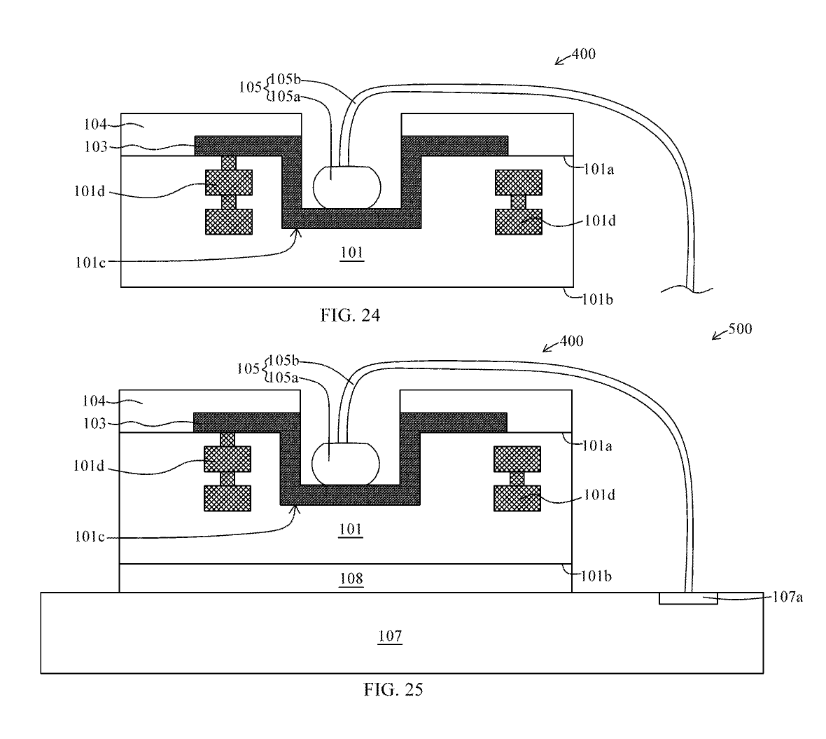

In some embodiments, an interconnect structure 105 is disposed after the disposing of the passivation 104 as shown in FIGS. 23 and 24. In some embodiments, the interconnect structure 105 is disposed within the recess 101c and surrounded by the conductive layer 103 and the passivation 104. In some embodiments, the interconnect structure 105 is disposed over and electrically connected to the conductive layer 103.

In some embodiments as shown in FIG. 23, the interconnect structure 105 is formed by disposing a conductive material over the conductive layer 103 exposed from the passivation 104, and then reflowing the conductive material. In some embodiments, the interconnect structure 105 is a conductive bump. In some embodiments, the interconnect structure 105 is formed by stencil pasting, ball dropping, reflowing, curing or any other suitable processes. In some embodiments, the semiconductor structure 200 is formed. In some embodiments, the semiconductor structure 200 has similar configuration as described above or illustrated in FIG. 3 or 4.

In some embodiments, the interconnect structure 105 including a stud 105a and a wire 105b is disposed over the conductive layer 103 as shown in FIG. 24. In some embodiments, the interconnect structure 105 is a wire bonding structure. In some embodiments, the stud 105a is disposed over the conductive layer 103 and within the recess 101c, and the wire 105b is extended from the stud 105 out of the recess 101c. In some embodiments, the interconnect structure 105 is formed by wire bonding processes. In some embodiments, the semiconductor structure 400 is formed. In some embodiments, the semiconductor structure 400 has similar configuration as described above or illustrated in any one of FIGS. 7-9.

In some embodiments, the semiconductor structure 400 is disposed over and electrically connected to a second substrate 107 as shown in FIG. 25. In some embodiments, the semiconductor structure 400 is attached to the second substrate 107 by an adhesive 108. In some embodiments, the wire 105b is bonded with a bond pad 107a of the second substrate 107. In some embodiments, the conductive layer 103 is electrically connected to the second substrate 107 by wire bonding processes. In some embodiments, a package 500 is formed, which has similar configuration as described above or illustrated in FIG. 9.

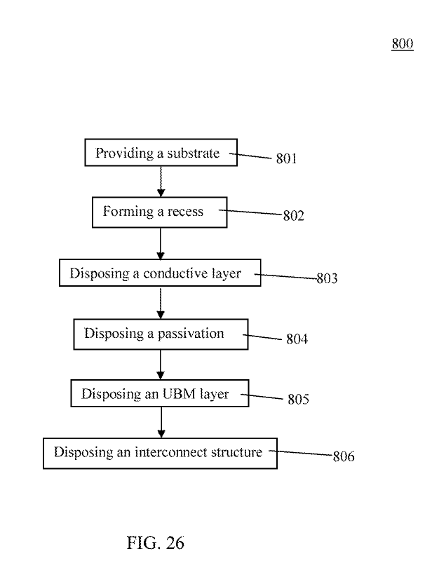

In the present disclosure, a method of manufacturing a semiconductor structure is also disclosed. In some embodiments, the semiconductor structure can be formed by a method 800 of FIG. 26. The method 800 includes a number of operations and the description and illustration are not deemed to be a limitation as the sequence of the operations. The method 800 includes a number of steps (801, 802, 803, 804, 805 and 806).

In step 801, a substrate 101 is provided or received, which is similar to the step 701. In step 802, a recess 101c is formed, which is similar to the step 702. In step 803, a conductive layer 103 is disposed, which is similar to the step 703. In step 804, a passivation 104 is disposed, which is similar to the step 704.

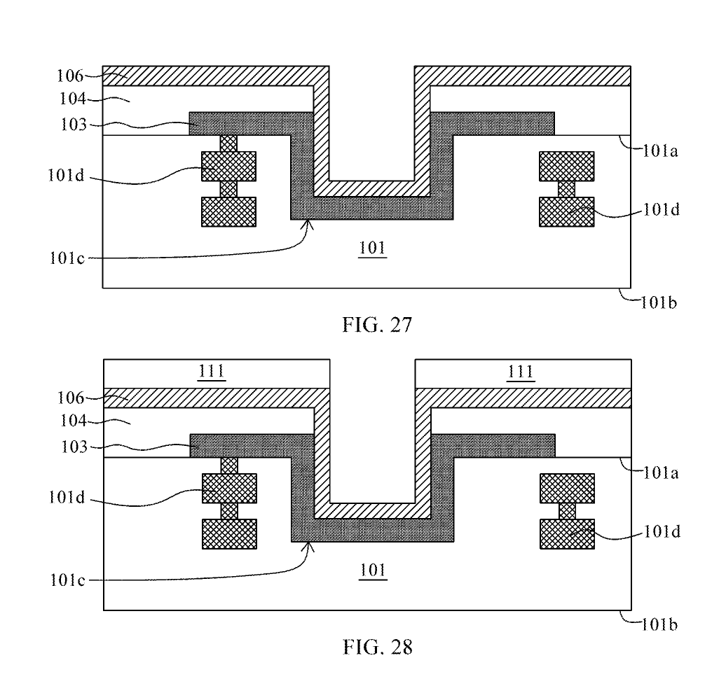

In step 805, an UBM layer 106 is disposed as shown in FIG. 27. In some embodiments, the UBM layer 106 is disposed over the passivation 104 and the conductive layer 103 exposed from the passivation 104. In some embodiments, the UBM layer 106 is disposed conformal to the conductive layer 103. In some embodiments, the UBM layer 106 is disposed by sputtering, electroplating or any other suitable processes.

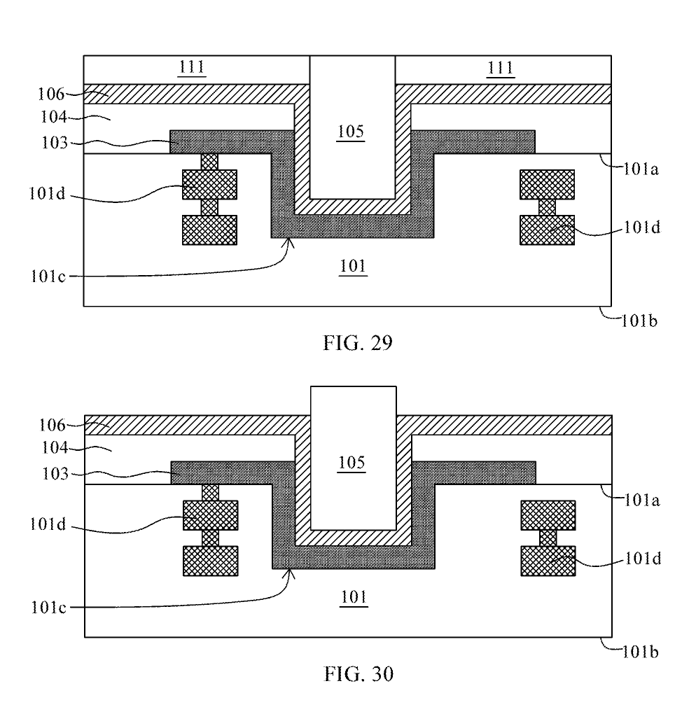

In step 806, an interconnect structure 105 is disposed over the UBM layer 106 as shown in FIGS. 28-31. In some embodiments, the interconnect structure 105 is disposed by disposing a third patterned mask 111 over the UBM layer 106 as shown in FIG. 28, disposing a conductive material over the conductive layer 103 exposed from the third patterned mask 111 as shown in FIG. 29, and then removing the third patterned mask 111 as shown in FIG. 30. In some embodiments, the interconnect structure 105 is formed by stencil pasting, ball dropping, reflowing, curing or any other suitable processes. In some embodiments, the interconnect structure 105 is surrounded by the UBM layer 106, the conductive layer 103 and the substrate 101. In some embodiments, the interconnect structure 105 is at least partially disposed within the recess 101c. In some embodiments, the interconnect structure 105 has similar configuration as described above or illustrated in FIG. 5 or 6.

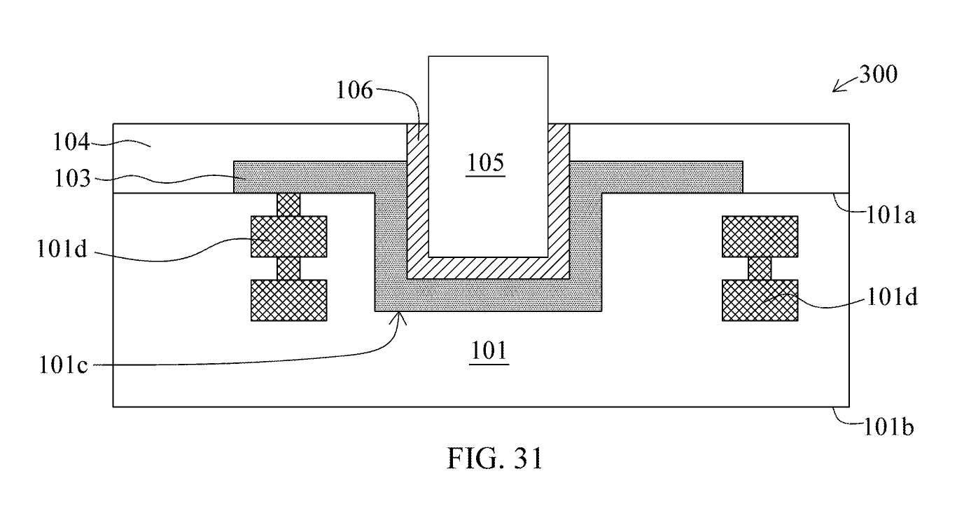

In some embodiments, a portion of the UBM layer 106 disposed over the passivation 104 is removed after the formation of the interconnect structure 105 as shown in FIG. 31. In some embodiments, the portion of the UBM layer 106 disposed over the passivation 104 is removed by etching or any other suitable processes. In some embodiments, a semiconductor structure 300 is formed, which has similar configuration as described above or illustrated in FIG. 5 or 6.

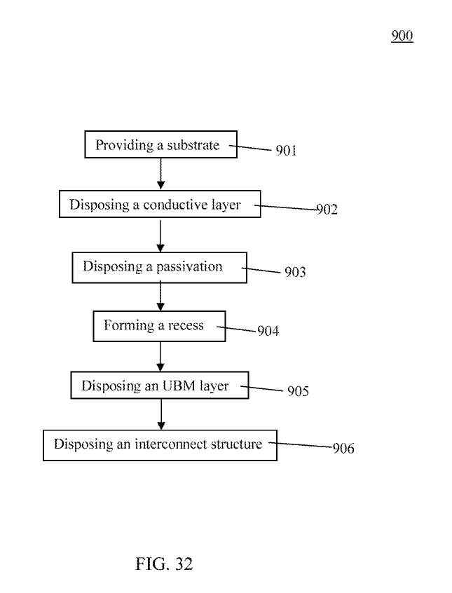

In the present disclosure, a method of manufacturing a semiconductor structure is also disclosed. In some embodiments, the semiconductor structure can be formed by a method 900 of FIG. 32. The method 900 includes a number of operations and the description and illustration are not deemed as a limitation as the sequence of the operations. The method 900 includes a number of steps (901, 902, 903, 904, 905 and 906).

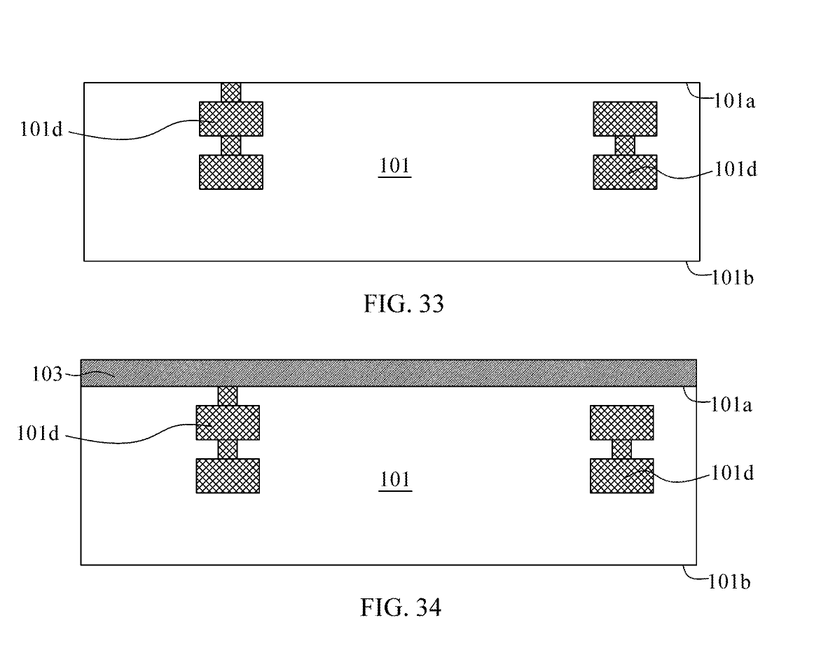

In step 901, a substrate 101 is provided or received as shown in FIG. 33, which is similar to the step 701 or 801.

In step 902, a conductive layer 103 is disposed over the substrate 101 as shown in FIG. 34. In some embodiments, the conductive layer 103 is disposed over the first surface 101a. In some embodiments, the conductive layer 103 is disposed by electroplating, sputtering or any other suitable operations. In some embodiments, the conductive layer 103 includes gold, silver, copper, nickel, tungsten, aluminum, palladium and/or alloys thereof. In some embodiments, the conductive layer 103 is electrically connected to the conductive structure 101d. In some embodiments, the conductive layer 103 is coupled with at least a portion of the conductive structure 101d.

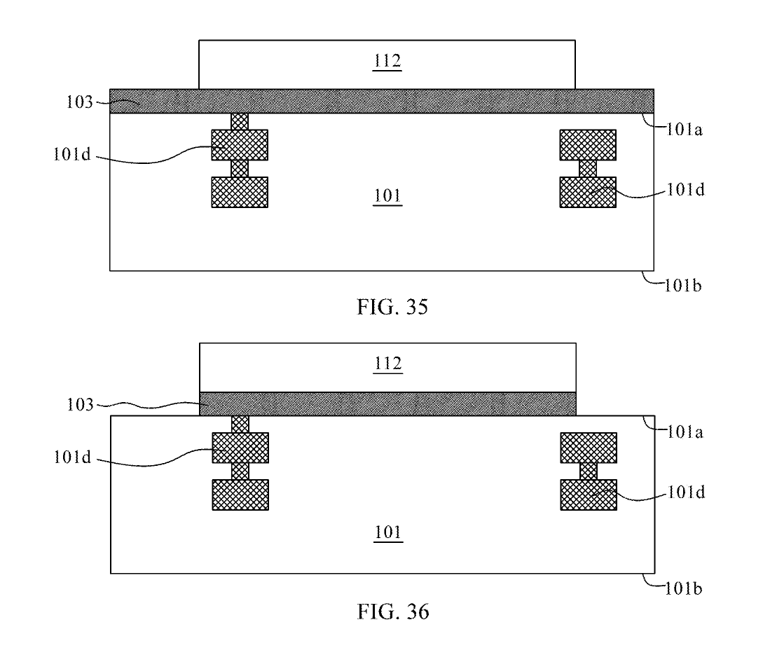

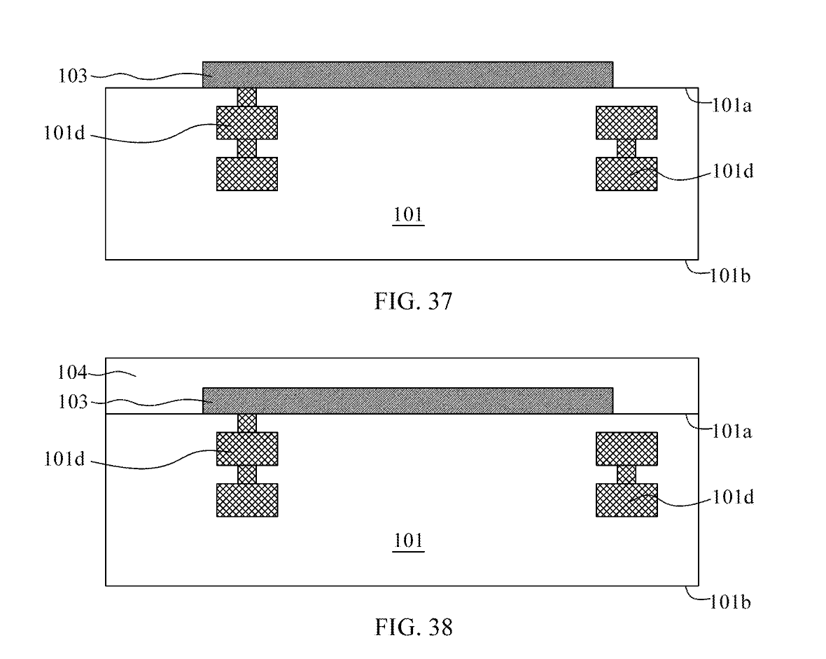

In some embodiments, some portions of the conductive layer 103 are removed as shown in FIGS. 35-37. In some embodiments, a fourth patterned mask 112 is disposed over the conductive layer 103 as shown in FIG. 35, and some portions of the conductive layer 103 exposed from the fourth patterned mask 112 are removed as shown in FIG. 36, and then the fourth patterned mask 112 is removed as shown in FIG. 37.

In some embodiments, the fourth patterned mask 112 is formed by disposing a photoresist (PR) over the conductive layer 103, and then removing a portion of the PR corresponding to the portions of the conductive layer 103 to be removed. In some embodiments, the fourth patterned mask 112 is removed by etching, stripping or any other suitable processes after the formation of the conductive layer 103.

In step 903, a passivation 104 is disposed as shown in FIG. 38. In some embodiments, the passivation 104 is disposed over the first surface 101a and the conductive layer 103. In some embodiments, the passivation 104 is disposed by CVD, PECVD, spin coating or any other suitable processes.

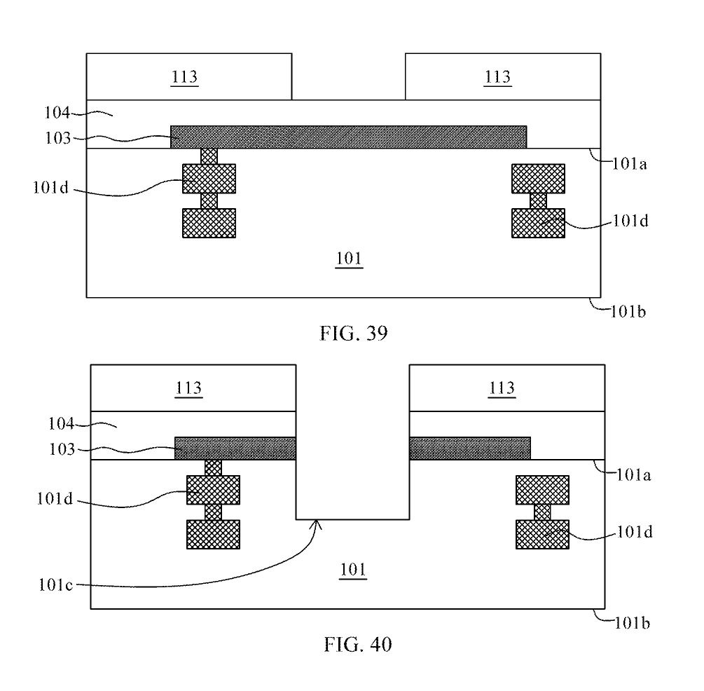

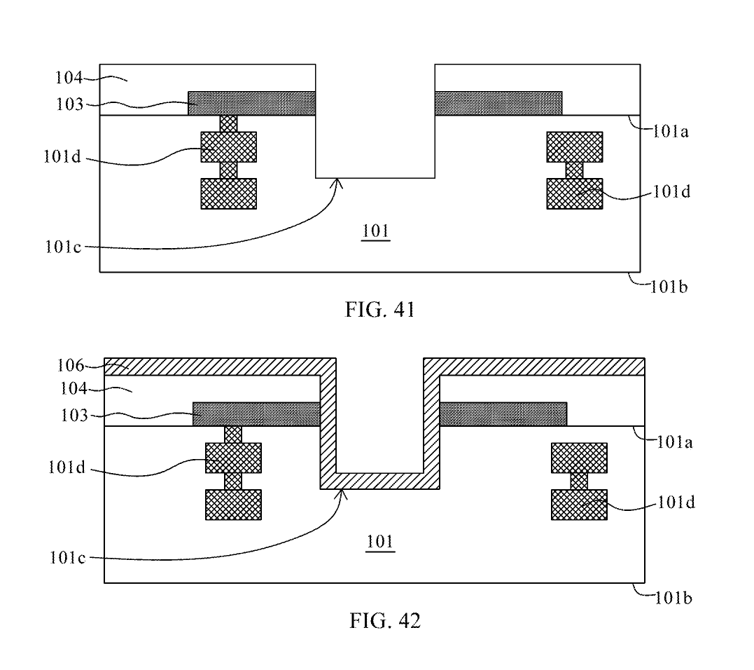

In step 904, a recess 101c is formed as shown in FIGS. 39-41. In some embodiments, the recess 101c is formed by disposing a fifth patterned mask 113 over the passivation 104 as shown in FIG. 39, removing a portion of the passivation 104 exposed from the fifth patterned mask 113, a portion of the conductive layer 103 and a portion of the substrate 101 as shown in FIG. 40, and then removing the fifth patterned mask 113 as shown in FIG. 41. In some embodiments, the recess 101c is formed by photolithography, etching and any other suitable processes. In some embodiments, the fifth patterned mask 113 is formed by disposing a photoresist (PR) over the passivation 104, and then removing a portion of the PR corresponding to the portion of the passivation 104 to be removed. In some embodiments, the fifth patterned mask 113 is removed by etching, stripping or any other suitable processes after the formation of the recess 101c.

In some embodiments, the recess 101c is recessed from the first surface 101a towards the second surface 101b. In some embodiments, the recess 101c is extended in a direction orthogonal to the first surface 101a or the second surface 101b. In some embodiments, the recess 101c has similar configuration as described above or illustrated in any one of FIGS. 10-12.

In step 905, an UBM layer 106 is disposed as shown in FIG. 42. In some embodiments, the UBM layer 106 is disposed over the passivation 104 and within the recess 101c. In some embodiments, at least a portion of the UBM layer 106 is coupled with the conductive layer 103 exposed from the passivation 104. In some embodiments, the UBM layer 106 is disposed by sputtering, electroplating or any other suitable processes.

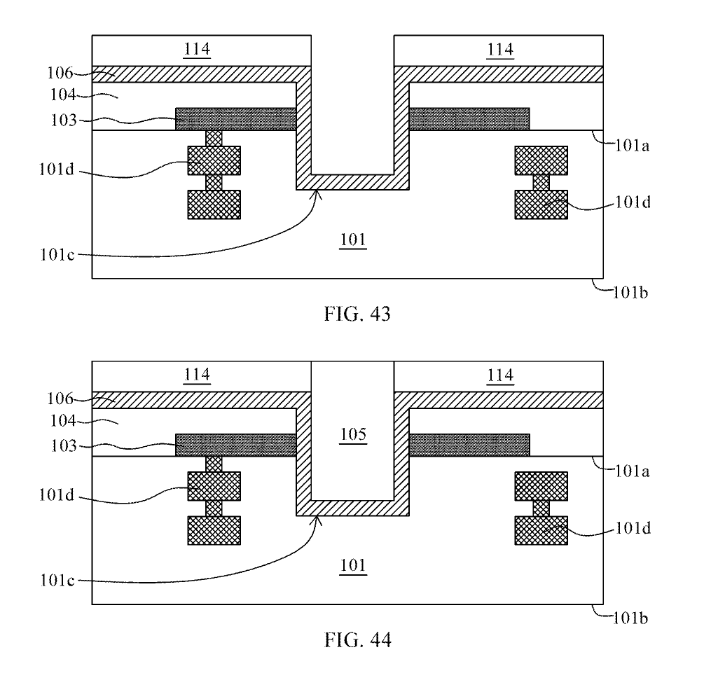

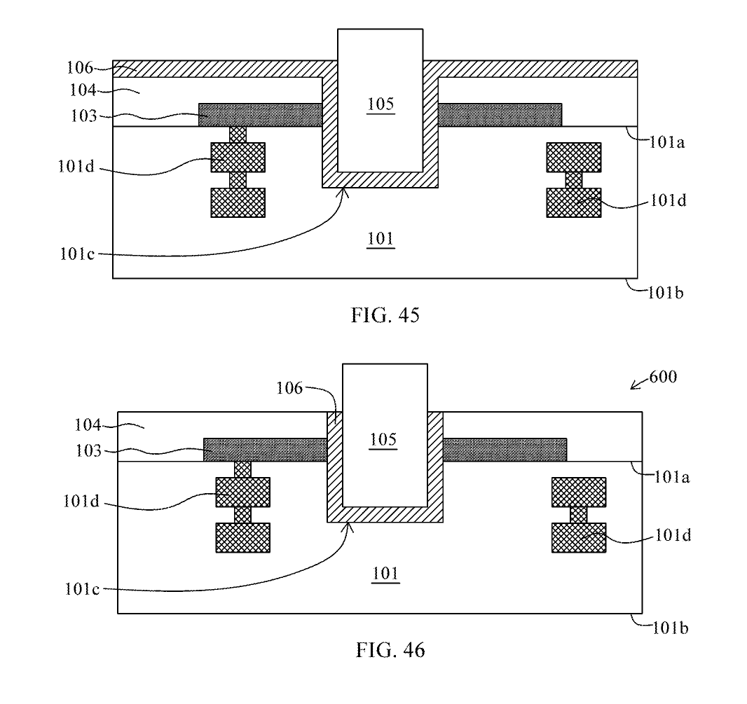

In step 906, an interconnect structure 105 is disposed as shown in FIGS. 43-46. In some embodiments, the interconnect structure 105 is disposed by disposing a sixth patterned mask 114 over the UBM layer 106 as shown in FIG. 43, disposing a conductive material over the conductive layer 103 exposed from the sixth patterned mask 114 as shown in FIG. 44, and then removing the sixth patterned mask 114 as shown in FIG. 45. In some embodiments, the interconnect structure 105 is formed by stencil pasting, ball dropping, reflowing, curing or any other suitable processes. In some embodiments, the interconnect structure 105 is surrounded by the UBM layer 106, the conductive layer 103 and the substrate 101. In some embodiments, the interconnect structure 105 is at least partially disposed within the recess 101c. In some embodiments, the interconnect structure 105 has similar configuration as described above or illustrated in any one of FIGS. 10-12.

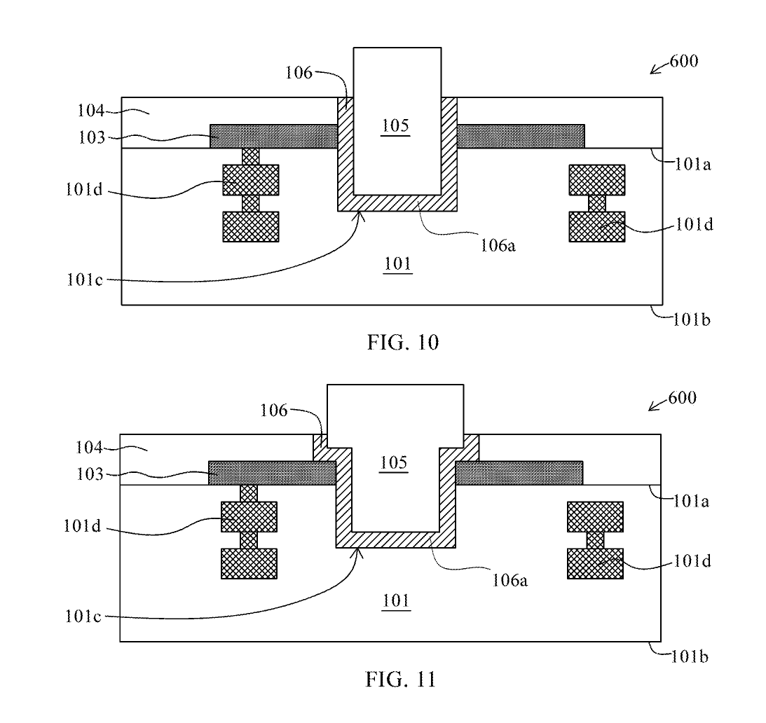

In some embodiments, a portion of the UBM layer 106 disposed over the passivation 104 is removed after the formation of the interconnect structure 105 as shown in FIG. 46. In some embodiments, the portion of the UBM layer 106 disposed over the passivation 104 is removed by etching or any other suitable processes. In some embodiments, the interconnect structure 105 is electrically connected to the conductive structure 101d through the conductive layer 103 and the UBM layer 106. In some embodiments, a semiconductor structure 600 is formed, which has similar configuration as described above or illustrated in FIG. 10 or 11.

Although the present disclosure and its advantages have been described in detail, it should be understood that various changes, substitutions and alterations can be made herein without departing from the spirit and scope of the disclosure as defined by the appended claims. For example, many of the processes discussed above can be implemented through different methods and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the disclosure of the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

What is claimed is:

1. A method of manufacturing a semiconductor structure, comprising:
providing a substrate;
forming a recess over the substrate;
disposing a conductive layer over the substrate; and
disposing a passivation over the substrate to at least partially cover the conductive layer.

2. The method of claim 1, wherein the conductive layer is disposed within the recess or conformal to a sidewall of the recess.

3. The method of claim 1, wherein the conductive layer is disposed by electroplating or sputtering.

4. The method of claim 1, wherein the recess is formed by disposing a patterned mask over the substrate and removing a portion of the substrate.

5. The method of claim 1, wherein the recess is formed by disposing a patterned mask over the passivation and removing a portion of the passivation, a portion of the conductive layer and a portion of the substrate.

6. The method of claim 1, wherein the recess is formed by photolithography and etching.

7. The method of claim 1, further comprising:
disposing an under bump metallization (UBM) layer within the recess exposed from the passivation; or
disposing an interconnect structure over the conductive layer to electrically connect the interconnect structure with the conductive layer; or
reflowing the interconnect structure; or
attaching the semiconductor structure over a second substrate; or
wire bonding the conductive layer with a second substrate.
